(19) United States
(12) Patent Application Publication
(10) Pub. No.: US 2015/0110141 A1
(43) Pub. Date: Apr. 23, 2015

(54) DRIVING CIRCUIT AND ILLUMINATION DEVICE HAVING LIGHT-EMITTING ELEMENTS

(71) Applicant: Wisdom Technologies Holding Limited, Hong Kong (CN)

(72) Inventor: Chat Hoi Mo, Wan Chai (CN)

(73) Assignee: Wisdom Technologies Holding Limited, Wan Chai (HK)

(21) Appl. No.: 14/358,728

(22) PCT Filed: Dec. 18, 2012
(86) PCT No.: PCT/CN2012/086881

§ 371 Date: May 16, 2014

(30) Foreign Application Priority Data
Jun. 20, 2012 (CN) 201220291830.0

(51) Int. Cl. H05B 33/08; H01S 5/06

(52) U.S. Cl. CPC H05B 33/0827; H01S 5/06; H05B 33/0896
USPC 372/38.02; 315/193

(57) ABSTRACT

The present invention discloses a driving circuit including a rectifying circuit and a first current-controlling circuit. Input terminals of the rectifying circuit are connected to output terminals of an AC power source. The first current-controlling circuit and a plurality of light-emitting elements be driven are connected in series, and then are connected between two output terminals of the rectifying circuit. The driving circuit further includes a plurality of switches and a switch-controlling circuit; the switches are connected in parallel with two terminals of one or some light-emitting elements connected in series to form many light-emitting element subunits. Control-signal output terminals of the switch-controlling circuit are connected to control terminals of the switches respectively, to control the switches in an ON-OFF state according to an instantaneous value of a DC voltage outputted from the rectifying circuit, for controlling an amount of light-emitting elements which should be lighten.

### TECHNICAL FIELD

The present invention relates to a driving circuit and an illumination device, and more particularly to a driving circuit and an illumination device having light-emitting elements.

### DESCRIPTION OF THE RELATED ART

Light-emitting element may convert electric energy into light energy, and is a common device for illuminating or displaying. The conventional light-emitting element comprises light-emitting diode (LED), organic light-emitting diode (OLED), polymer light-emitting diode (PLED), and laser diode (LD), etc. Take the LED as an example, FIG. 1 is a circuit diagram of a conventional driving circuit of LEDs, which comprises a rectifying circuit 100 and a first current-controlling circuit 200. The driving circuit drives a number of light-emitting elements connected in series. Input terminals of the rectifying circuit 100 are connected to output terminals of an alternating-current (AC) power source. The first current-controlling circuit 200 is connected to four light-emitting elements (D1, D2, D3, D4), which should be driven, in series, and then they are connected between two output terminals of the rectifying circuit 100. The rectifying circuit 100 is configured for rectifying the inputted alternating-current power source (AC) and outputting a direct-current (DC) voltage. The rectifying-circuit 100 as shown in FIG. 1 is a full-wave rectifying circuit consisted of four diodes (D101, D102, D103, and D104) in series. The first current-controlling circuit 200 is configured for controlling the current passing through the LEDs in series in the range of the normal operation current of the LEDs, so as to avoid the current passing through the LEDs is too large to damage the LEDs, and ensure the LEDs to operate safely. The driving circuit as shown in FIG. 1 can drive the LEDs to operate steadily. However, since the AC voltage is sine waves as shown in FIG. 2, the DC voltage outputted by the rectifying circuit 100 are consisted of a plurality of half waves in a same direction as shown in FIG. 3, and instantaneous values thereof constantly change at different time of one period. The driving circuit drives the four LEDs, and the operation voltage of a single LED is U0 (generally from 2 to 4V), and the voltage consumed by the number of LEDs is 4×U0 (from 8 to 16V). The instantaneous values of the DC voltage outputted by the rectifying circuit 100 are U, and the voltage consumed by the first current-controlling circuit 200 is U−4×U0. Therefore, the supernumerary part of the DC voltage of the driving circuit at any one time after rectifying are pointlessly consumed by the first current-controlling circuit 200, and cannot be adequately utilized, thus the efficiency of the driving circuit converting the electric energy into the light energy is low.

### SUMMARY OF THE INVENTION

The problem solved by the present invention is to provide a driving circuit and an illumination device having light-emitting elements, to overcome the disadvantages of the conventional prior art, and with high efficiency of converting electrical energy to light energy.

In accordance with an aspect, the present invention provides a driving circuit for light-emitting elements. The driving circuit comprises a rectifying circuit and a first current-controlling circuit; input terminals of the rectifying circuit is connected to output terminals of an AC power source, the first current-controlling circuit and a plurality of light-emitting elements are connected in series, and then are connected between two output terminals of the rectifying circuit; the driving circuit further comprises a plurality of switches and a switch-controlling circuit; the switches is connected in parallel with two terminals of one or more light-emitting elements connected in series to form a plurality of light-emitting element subunits; control-signal output terminals of the switch-controlling circuit are connected to terminals of the switches respectively, to control the switches in ON-OFF state according to an instantaneous value of a DC voltage outputted from the rectifying circuit, for controlling an amount of light-emitting elements which should be lighten.

In accordance with another aspect, the present invention also provides an illumination device having light-emitting elements. The illumination device comprises a driving circuit and a plurality of light-emitting elements connected in series, and the driving circuit is the above-described driving circuit.

In summary, the driving circuit and the illumination device for the light-emitting elements of the present invention, increase the plurality of the switches and the switch-controlling circuit. Each of the switches is connected to two terminals of one light-emitting element or some light-emitting elements connected in series. The switch-controlling circuit controls the switches in the on state or in the off state according to the instantaneous value of the DC voltage outputted from the rectifying circuit, for controlling the amount of the light-emitting elements which should be lighten. Because the amount of the lighten light-emitting elements at the moment is determined by the instantaneous value of the DC voltage, the residuary portion of the instantaneous value of the DC voltage which is applied to the first current-controlling circuit, is little, and the most thereof are used to light the light-emitting elements. Therefore, the driving circuit and the illumination device for the light-emitting elements of the present invention have high efficiency of converting the electrical energy into the light energy.

### BRIEF DESCRIPTION OF THE DRAWINGS

The above objects and advantages of the present invention will become more readily apparent to those ordinarily skilled in the art after reviewing the following detailed description and accompanying drawings, in which:

FIG. 1 is a circuit diagram of a driving circuit of LEDs in prior art;

FIG. 2 is a waveform diagram of an AC power source inputted to the driving circuit as shown in FIG. 1;

FIG. 3 is a waveform diagram of a DC voltage outputted from the AC power source of the driving circuit in FIG. 1 that passing through a rectifying circuit;

FIG. 4 is a circuit diagram of a driving circuit for light-emitting elements in accordance with a first exemplary embodiment;

FIG. 5 is a structure view of light-emitting element subunits when using four switches to control fifteen light-emitting elements in the first exemplary embodiment;

FIG. 6 is a structure view of light-emitting element subunits when using four switches to control twenty light-emitting elements in the first exemplary embodiment;

FIG. 7 is a structure view of light-emitting element subunits of a driving circuit in accordance with a second exemplary embodiment;

FIG. 8 is a structure view of light-emitting element subunits of a driving circuit in accordance with a third exemplary embodiment;

FIG. 9 is a structure view of light-emitting element subunits of a driving circuit in accordance with a fifth exemplary embodiment;

FIG. 10 is a driving circuit diagram of light-emitting element of a driving circuit in accordance with a sixth exemplary embodiment.

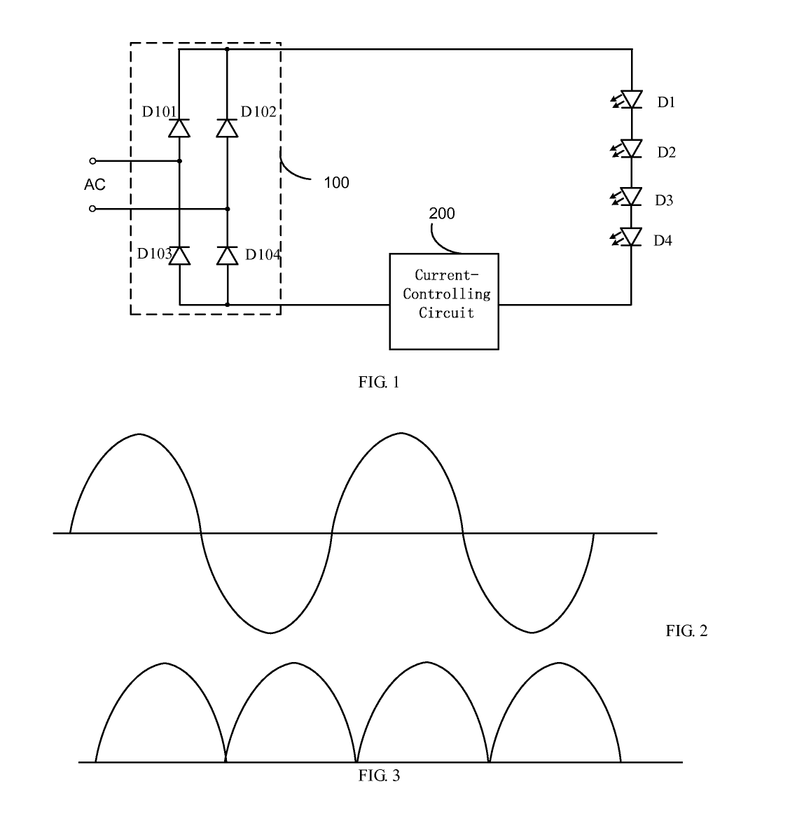

### DETAILED DESCRIPTION OF PREFERRED EMBODIMENTS

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

The following will cooperates exemplary embodiments and diagrams to describe the present invention in detail.

### First Exemplary Embodiment

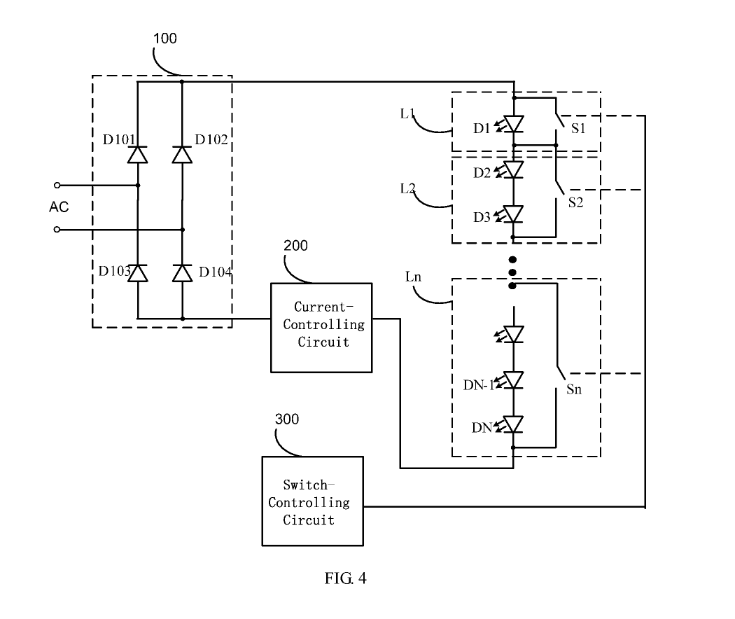

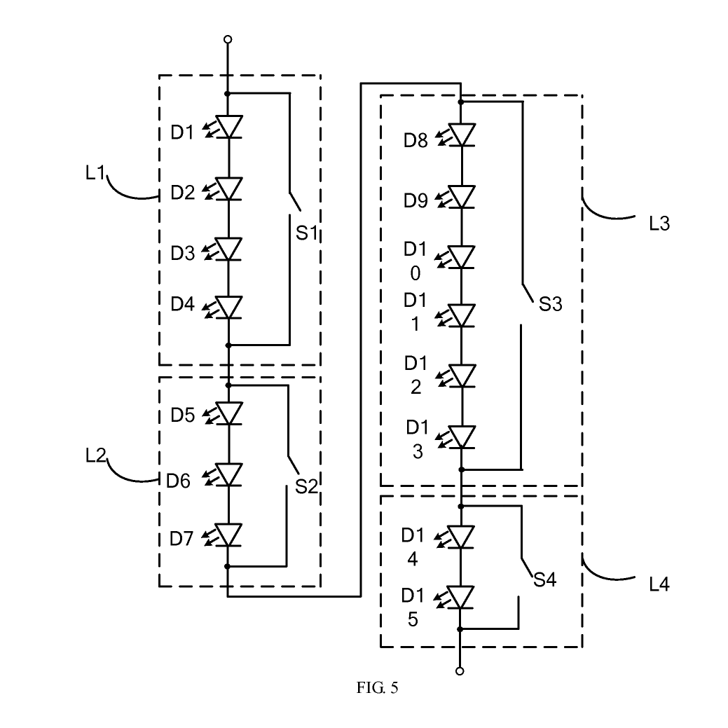

FIG. 4 is a circuit diagram of a driving circuit of a light-emitting element in accordance with a first exemplary embodiment of the present invention. The driving circuit of the light-emitting element comprises a rectifying circuit 100, a first current-controlling circuit 200, a plurality of switches (S1, S2, . . . , Sn), and a switch-controlling circuit 300.

Wherein, the rectifying circuit 100 is a full-wave rectifying circuit consisted of four diodes D101, D102, D103, D104. Input terminals of the rectifying circuit 100 are connected to output terminals of an alternating-current input power source AC, and configured for rectifying the alternating-current input power source AC (waves as shown in FIG. 2) into a direct-current voltage (waveform as shown in FIG. 3). It should be noted that, the rectifying circuit 100 also can be a half-wave rectifying circuit consisted of one or two diodes, instead of the full-wave rectifying circuit consisted of four diodes.

The first current-controlling circuit 200 and N light-emitting elements (D1, D2, D3, . . . , DN−1, DN) be driven, are connected in series, and then they are connected between two output terminals of the rectifying circuit 100. The first current-controlling circuit 200 is configured for controlling the current passing through the light-emitting elements in an operation-current range of the light-emitting elements. The first current-controlling circuit 200 may be performed by a single resistor, and the resistor is used to limit the current passing through the light-emitting elements no more than a maximum value of the operation current; alternatively, it may be performed by a constant-current circuit, configured for making the current passing through the light-emitting elements be throughout a constant value; alternatively, it may be a constant-power circuit or an over-current shutdown circuit. In addition, as connected in series, the sequence of series connecting of the first current-controlling circuit 200 and the N light-emitting elements will not influence the operation of the whole circuit. In this exemplary embodiment, the light-emitting elements may be LED, OLED, PLED or LD.

In the plurality of switches, each of the switches is connected in parallel between two terminals of one light-emitting element or a plurality of light-emitting elements connected in series, to form a plurality of light-emitting element subunits (L1, L2, . . . , Ln). Since the plurality of light-emitting elements are connected in series, the formed light-emitting element subunits L1 to Ln are connected in series, therefore, the sequence of the plurality of the light-emitting element subunits connected in series will not influence the operation of the whole circuit. The sequence of connecting the plurality of the light-emitting element subunits may be random, such as the sequence of L2, L5, L3, . . . , Ln, L1, L4. The random sequence thereof can generate a same effect.

Controlling-signal output terminals of the switch-controlling circuit 300 are connected to a control terminal of each of the switches respectively, to output control signals to control ON/OFF states of the switches respectively. Thus, an instantaneous value of the DC voltage outputted from the rectifying circuit 100 control the ON/OFF states of the switches respectively, to control the amount of the light-emitting elements which should be lighten. In detail, the switch-controlling circuit 300 calculates the amount of the light-emitting elements which should be lighten according to a relational expression of (U−ΔU1)/U0, and the amount of the light-emitting elements which should be lighten is an integral part of the calculated result of the relational expression, wherein U represents the instantaneous value of the DC voltage outputted from the rectifying circuit at the current time, ΔU1 represents an operation voltage required by the first current-controlling circuit 200 operating steadily, and U0 represents an operation voltage of a single light-emitting element (generally in a range from 2 to 4V). For example, taking the LED as the light-emitting element, if the instantaneous value U of the DC voltage outputted from the rectifying circuit 100 is equal to 101V, ΔU1 is equal to 5V and U0 is equal to 2.4V, thus it should light forty LEDs at the current time. For another example, if the instantaneous value U of the DC voltage outputted from the rectifying circuit 100 is equal to 105V, ΔU1 is equal to 5V and U0 is equal to 2.4V, thus a calculating result is 41.67 according to the above expression, and it should light forty-one LEDs at the current time. The forty-one lighten LEDs consume the voltage of 98.4V, thus the residuary voltage of 6.6V, which is calculated by subtracting the instantaneous value of 105V at the current time by the voltage of 98.4V, is self-adaptively adjusted and supplied on the first current-controlling circuit 200. At this time, there may be a voltage of 1.6V which is not effectively used, and it wastes little power. After calculating the amount of the light-emitting elements be lighten, the switch-controlling circuit 300 controls the ON/OFF states of the plurality of the light-emitting elements. The LEDs connected in parallel with the switch in the ON state are shorted, and the LEDs connected in series with the switch in the OFF state are lighten, therefore, the switch-controlling circuit 300 controls the amount of the switches in the off states, thus it can control the amount of the lighten LEDs.

For example, as shown in FIG. 5, this shows a condition of using four switches to control fifteen light-emitting elements. In FIG. 5, a first switch S1 is connected in parallel between two terminals of four light-emitting elements connected in series, to form a first light-emitting element subunit L1; a second switch S2 is connected in parallel between two terminals of three light-emitting elements connected in series, to form a second light-emitting element subunit L2; a third switch S3 is connected in parallel between two terminals of six light-emitting elements connected in series, to form a third light-emitting element subunit L3; and a fourth switch S4 is connected in parallel between two terminals of two light-emitting elements connected in series, to form a fourth light-emitting element subunit L4.

Therefore, the switch-controlling circuit controls all of the four switches S1, S2, S3 and S4 in the OFF state, thus all of the fifteen light-emitting elements are lighten. When controlling the switch S1 in the ON state, the four light-emitting elements D1, D2, D3, D4 connected in parallel with the switch S1 are shorten, thus the amount of the lighten light-emitting elements is reduced by 4, that is, eleven light-emitting elements are lighten. Then if the switch S3 is in the ON state, the six light-emitting elements connected in parallel with the switch S3 are shorten, the amount of lighten light-emitting elements is then further reduced by six and change to be five. At this time, if the switch S1 is controlled to be in the OFF state, the amount of light-emitting elements be lighten is added by 4, and changes from five to nine. That is, when the switch of each light-emitting element subunit is in the ON state, the amount of lighten light-emitting elements should be subtracted by the amount of light-emitting elements connected in parallel with the switch in the ON state. The switch-controlling circuit controls different combinations of the four switches in the ON or OFF state, such that the amount of lighten light-emitting elements comprises 0 (all of the four switches in the ON state), 2 (only the switch S4 in the OFF state, and other switches in the ON state), 3 (only the switch S2 in the OFF state, and other switches in the ON state), 4 (only the switch S1 in the OFF state, and other switches in the ON state), 5 (the switches S2 and S4 in the OFF state, and other switches in the ON state), 6 (only the switch S3 in the OFF state, and other switches in the ON state), 7 (the switches S1 and S2 in the OFF state, and other switches in the ON state), 8 (the switches S3 and S4 in the OFF state, and other switches in the ON state), 9 (the switches S2 and S3 in the OFF state, and other switches in the ON state), 10 (the switches S1 and S3 in the OFF state, and other switches in the ON state), 11 (the switches S2, S3 and S4 in the OFF state, and other switch in the ON state), 12 (the switches S1, S3 and S4 in the OFF state, and other switch in the ON state), 13 (the switches S1, S2 and S3 in the OFF state, and other switch in the ON state), 15 (all of the 4 switches in the OFF state). That is, the switch-controlling circuit controls the four switches in the ON state or OFF state respectively, so as to control 0, 2 to 13, 15 light-emitting elements to be lighten, however, it cannot control 1 or 14 light-emitting elements to be lighten.

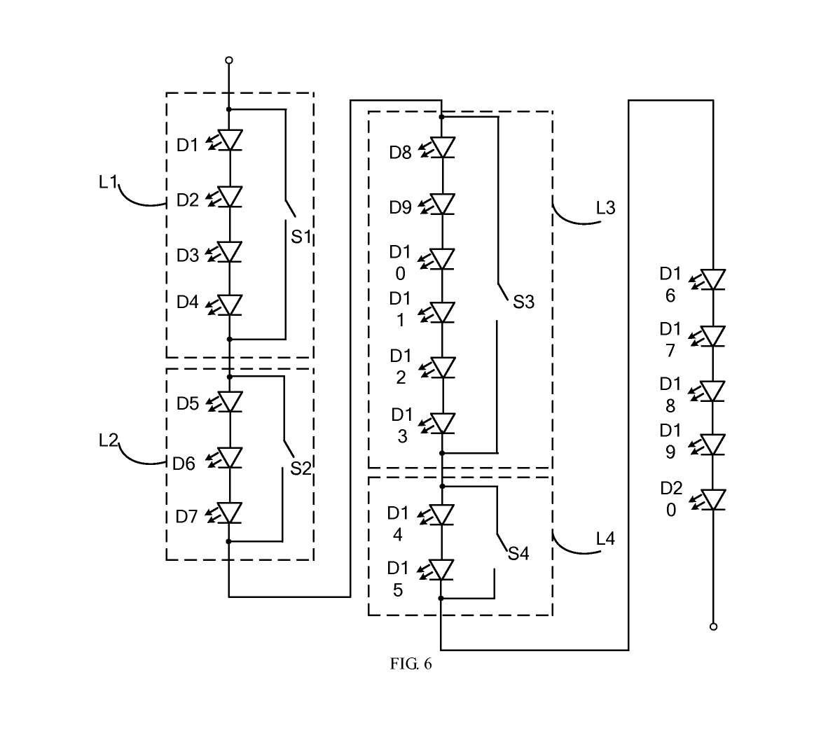

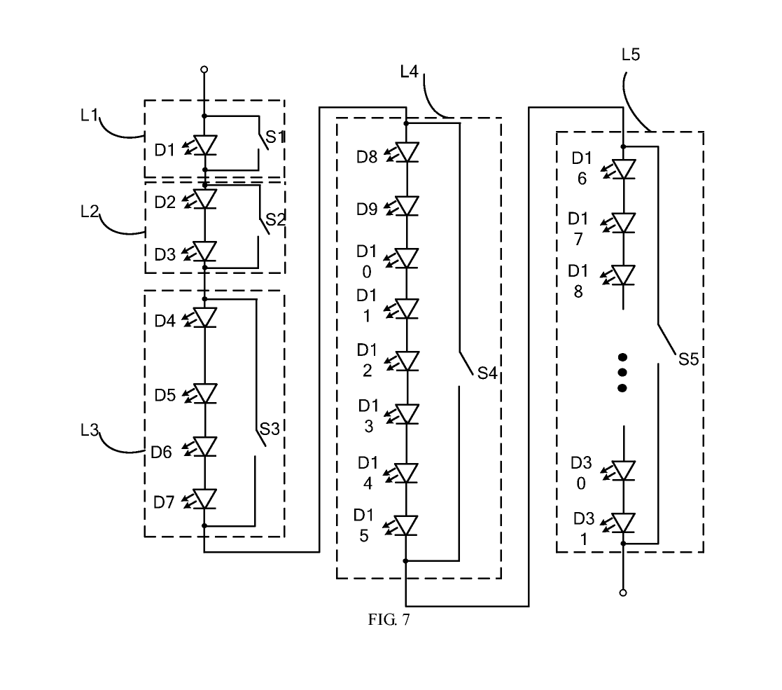

As shown in FIG. 6, which shows a condition of using four switches to control twenty light-emitting elements on the base of the light-emitting element subunits as shown in FIG. 5, the connection of the four switches and fifteen light-emitting elements is same to those of FIG. 5, and only residuary five light-emitting elements are not related to any switches. That is, the condition as shown in FIG. 5 is the amount N1 of light-emitting elements controlled by the switches equal to the amount N of light-emitting elements which should be driven, while the condition as shown in FIG. 6 is the amount N1 of light-emitting elements controlled by the switches less than the amount N of light-emitting elements which should be driven. Therefore, in FIG. 6, the residuary five light-emitting elements, which are not related to any switch, are throughout lighten, that is, the amount of minimal lighten light-emitting elements is five, and it can control 5, 7 to 18, or 20 light-emitting elements to be lighten, and cannot control 0-4, 6 or 19 light-emitting elements to be lighten. The light-emitting element subunits as shown in FIG. 6 cannot control more light-emitting elements to be lighten, however, it also be a useful structure. It should be noted that, the switches of FIG. 5 and FIG. 6 may be performed by electronic switch, such as NPN transistor, PNP transistor, field-effect transistor FET, metal oxide semiconductor field-effect transistor MOSFET, field-effect transistor, silicon controlled rectifier SCR, dual-directional silicon controlled rectifier DSCR, photo transistor, etc., or other controllable switch. The rectifying circuit 100, the first current-controlling circuit 200, the light-emitting elements, the switches and the switch-controlling circuit may be independent with each other, alternatively, one or some thereof may be integrated in an IC chip, thus can conveniently produce and improve the reliability.

When the instantaneous value of the DC voltage outputted from the forestage rectifying circuit 100 is a certain value, the corresponding switches are controlled to be in the ON or OFF state, to control the amount of lighten light-emitting elements. The driving circuit of the light-emitting element of the exemplary embodiment adds the switches and the switch-controlling circuit, to adjust the amount of lighten light-emitting elements along with the change of the instantaneous value of the forestage AC power source. Therefore, most of the power of the AC power sources is consumed on the light-emitting elements to be converted into light energy, and the voltage consumed on the current-controlling circuit is kept in a lower value, such that the electric energy of the AC power source can be maximally converted into the light energy, and improve the converting efficiency.

The exemplary embodiment further provides an illumination device having light-emitting element, which comprises a driving circuit and a plurality of light-emitting elements connected in series. The driving circuit may be the above-described driving circuit for the light-emitting elements. The driving circuit can maximally convert the electric energy of the AC power source into the light energy of the light-emitting elements which should be driven, and it can improve the converting efficiency, thus the illumination device of the exemplary embodiment has a higher converting efficiency.

### Second Exemplary Embodiment

Differences between this exemplary embodiment and the first exemplary embodiment are that, in this exemplary embodiment there are n light-emitting element subunits connected in serial, and amounts of light-emitting elements connected in parallel with switches of each of the n light-emitting element subunits are configured as a sequence consisted of the powers of 2. However, in the first exemplary embodiment, amounts of light-emitting elements connected in parallel in each of the light-emitting elements subunits are random, thus some numbers (such as 1, or 14) cannot be performed by the combinations, and it cannot completely provide the control of lightening one to the number of the whole light-emitting elements in series. In this exemplary embodiment, the amounts of the light-emitting elements connected in parallel with each switches are set to be the powers of 2, thus it can satisfy any one number from 1 to N1, and the sum of the amounts of the light-emitting elements of each of the light-emitting element subunits is 2ⁿ−1, such that the combinations of the switches in the on state or in the off state can light light-emitting elements from 0 to N1.

In detail, in the driving circuit, the amount of the switches is n, and an m-th switch is connected in parallel between two terminals of Am light-emitting elements connected in series, to form an m-th light-emitting element subunit, wherein m is from 1 to n. That is, a first switch is connected in parallel between two terminals of A1 light-emitting elements connected in series, to form a first light-emitting element subunit L1; a second switch is connected in parallel between two terminals of A2 light-emitting elements connected in series, to form a second light-emitting element subunit L2; a third switch is connected in parallel between two terminals of A3 light-emitting elements connected in series, to form a third light-emitting element subunit L3; . . . , and so on. An n-th switch is connected in parallel between two terminals of An light-emitting elements connected in series, to form a n-th light-emitting element subunit Ln. The n light-emitting element subunits are connected in series, and the sum of the amounts of the light-emitting elements of each of the light-emitting element subunits are N1. The n numbers consisted of from A1 to An, can be combined to be any one number from 1 to N1. The connection and the operation principle of the rectifying circuit, the first current-controlling circuit, the switches, and the switch-controlling circuit of the driving circuit are same to those of the first exemplary embodiment, and it will not be described in following. In this exemplary embodiment, Am is 2ⁿ⁻¹, and the amounts A1, A2, A3, Am of the light-emitting elements connected in parallel in each of the n switches, are a number sequence consisted of numbers from 2¹⁻¹ to 2^{m-1}, and it can control the operation of the N1 light-emitting elements connected in series, N1=2¹⁻¹+2²⁻¹+2³⁻¹ . . . +2ⁿ⁻¹=2ⁿ−1, to lighten light-emitting elements of any one number from 1 to N1.

As shown in FIG. 7, which is a structural view of the light-emitting element subunits of the exemplary embodiment, there are five switches to control the operation of thirty-one light-emitting elements, to form five light-emitting element subunits, for lighting the light-emitting elements of any number of 0-31. That is, n=5, A1=1, A2=2, A3=4, A4=8, A5=16, a first switch S1 is connected in parallel with two terminals of one light-emitting element (D1), to form a first light-emitting element subunit L1; a second switch S2 is connected in parallel with two terminals of two series-connected light-emitting elements (D2 and D3), to form a second light-emitting element subunit L2; a third switch S3 is connected in parallel with two terminals of four series-connected light-emitting elements (D4-D7), to form a third light-emitting element subunit L3; a fourth switch S4 is connected in parallel with two terminals of eight series-connected light-emitting elements (D8-D15), to form a fourth light-emitting element subunit L4; and a fifth switch S5 is connected in parallel with two terminals of sixteen series-connected light-emitting elements (D16-D31), to form a fifth light-emitting element subunit L5. The five light-emitting element subunits are connected in series, and the sum of the light-emitting elements of each of the light-emitting element subunits N1 is equal to 31.

When all of the switches are in the off state, the whole of the thirty-one light-emitting elements are lighten. When the third switch S3 is in the ON state, the four light-emitting elements connected in parallel with the third switch S3 are shorted by the third switch S3, and the current only passes through the third switch S3 and does not pass through the four light-emitting elements connected in parallel with the third switch S3. That is, the amount of lighten light-emitting elements is subtracted by 4. If the fifth switch S5 is in the ON state simultaneously, the sixteen light-emitting elements connected in parallel with the fifth switch S5 are shorted. That is, the amount of lighten light-emitting elements is further subtracted by 16, and the light-emitting elements of the number of 31−4−16=11 are lighten, and the twenty light-emitting elements are shorted. Therefore, it can control the switches S1 to S5 in the ON or OFF state, to control the light-emitting elements of any number from 1 to 31 to be lighten. The five light-emitting element subunits are connected in series, thus it does not limit the first light-emitting element subunit L1 must be connected to the second light-emitting element subunit L2 in sequence, and then connected to L3, L4, L5 in sequence. As long as the five subunits are connected in series, any sequence thereof may be suitable, and the result thereof is same and not altered. That is, the sequence may be L5, L3, L2, L1, L4, or may be L2, L4, L5, L3, L1. As long as the five light-emitting element subunits are connected in series, and the switches S1 to S5 are controlled in the ON state or OFF state, thus the light-emitting elements of any number from 1 to 31 can be lighten.

When the amounts of the light-emitting elements connected in parallel with each of the switches are set to be the powers of 2, the switch-controlling circuit 300 may have a preferable controlling mode. Take “1” as OFF state of a switch, and take “0” as ON state of a switch. The states of the switches S1 to S5 form a number according to the sequence of S5, S4, S3, S2, S1. If eleven light-emitting elements are lighten, the number is “01011”, which is “01011” of binary, and “11” of decimal. Therefore, for n switches, the states of the switches S1 to Sn are arranged from right to left, to form a number of “Sn . . . 535251”, which is a binary number, and a corresponding decimal number is the amount of lighten light-emitting elements. The switch-controlling circuit 300 can output control signals consisted of the binary number to control terminals of the switches S1 to Sn respectively. If the control terminal of the switch receives the control signal with the binary number of “1”, the switch is controlled in the OFF state. If the control terminal of the switch receives the control signal with the binary number of “0”, the switch is controlled in the ON state. Therefore, it may correspondingly control the states of the switches S1 to Sn, to control the light-emitting elements of any number from 0 to N1 to be lighten.

It should be noted that, the above controlling mode of binary number is a preferable controlling method, but it is not limited to this single method. Some similar methods may achieve the same effect, and can select any number of the light-emitting elements to operate normally, and the similar methods are justly different from the mode of the binary number, but they also are used in the driving circuit for the light-emitting elements.

The driving circuit for the light-emitting elements of the exemplary embodiment set the amounts of the light-emitting elements connected in parallel with each of the switches to be the power of 2, and change the combinations of the switches in the ON or OFF state to light the light-emitting elements of any number from 0 to N1. Therefore, it can adjust the amount of the lighten light-emitting elements according to the instantaneous value of the DC voltage outputted from the forestage rectifying circuit 100, thus, it can be controlled accurately, and can more accurately control the amount of the lighten light-emitting elements to further improve the converting efficiency.

### Third Exemplary Embodiment

Differences between this exemplary embodiment and the second exemplary embodiment are that, in this exemplary embodiment, the amounts of light-emitting elements connected in parallel with each of the switches are set to be the power of 2, but the sum N1 of the light-emitting elements of each of the light-emitting element subunits is larger than 2ⁿ⁻¹−1 but less than 2ⁿ−1, that is, the it does not distribute the light-emitting elements of the powers of 2 to the switches respectively. In the second exemplary embodiment, N1 is equal to 2ⁿ−1, thus it can distribute the light-emitting elements of the powers of 2 to the switches respectively. This exemplary embodiment cannot distribute the light-emitting elements of the power of 2, but the combinations still can select any number from 1 to N1.

In the driving circuit, the amount of the switches is n, and an m-th switch is connected in parallel with two terminals of Am light-emitting elements connected in series, to form an m-th light-emitting element subunit. In this exemplary embodiment, when m is in a range of 1 to n−1, Am is 2^{m-1}; and when m is equal to n, An is equal to N1−(2ⁿ⁻¹−1). That is, the amounts of the light-emitting elements of the fore (n−1) light-emitting element subunits are still set to be the power of 2. The first switch is connected in parallel with one light-emitting element, the second switch is connected in parallel with two light-emitting elements connected in series, the third switch is connected in parallel with four light-emitting elements connected in series, . . . , and so on. The (n−1)-th switch is connected to the 2ⁿ⁻² light-emitting elements connected in series, and the last n-th switch is connected in parallel between two terminals of residuary light-emitting elements connected in series, and the amount of the light-emitting elements of the n-th group is N1−(2ⁿ⁻¹−1), and is less than 2ⁿ⁻¹ of the second exemplary embodiment. The n switches are connected to the light-emitting elements to form the n light-emitting element subunits connected in series, to control the operation of the N1 light-emitting elements (less than 2ⁿ−1) connected in series, and lighten the light-emitting elements of any number from 0 to N1. When the amount of the light-emitting elements, which should be operated normally, is from 0 to 2ⁿ⁻¹−1, the control method is same to that of the second exemplary embodiment. When the amount of the light-emitting element, which are should operate normally, is larger than 2ⁿ⁻¹−1, the n-th switch is firstly controlled in the OFF state and the light-emitting elements connected in parallel with the n-th switch are lighten, and the residuary light-emitting elements may be controlled by controlling the first to the (n−1)-th switches by the above controlling method.

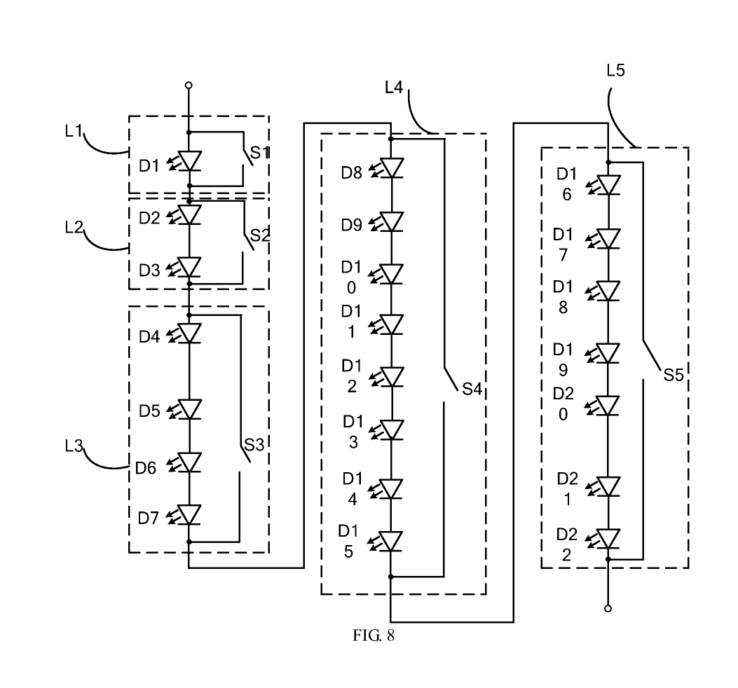

As shown in FIG. 8, which is a structural view of the light-emitting element subunits of the exemplary embodiment, there are five switches to control the operation of twenty-two light-emitting elements, to form five light-emitting element subunits, for lighting the light-emitting elements of any number of 0-22. That is, n=5, A1=1, A2=2, A3=4, A4=8, A5=7. The first light-emitting element subunit L1, the second light-emitting element subunit L2, the third light-emitting element subunit L3, the fourth light-emitting element subunit L4 are same to those of the second exemplary embodiment, but the fifth light-emitting element subunit L5 is different from that of the second exemplary embodiment. The fifth switch S5 is connected in parallel with two terminals of the seven light-emitting elements (D16-D22) connected in series, to form the fifth light-emitting element subunit L5. The five light-emitting element subunits are connected in series, and the sum of the light-emitting elements of each of the light-emitting element subunits N1 is equal to 22.

If the amount of the light-emitting elements which should be lighten is from 0 to 15, the switch-controlling circuit controls the switch S5 in the on state, and the controlling method of the switches S1-S4 is same to that of the second exemplary embodiment and controls the switches S1-S4 in the ON or OFF state. If the amount of the light-emitting elements be lighten is larger than fifteen, the switch-controlling circuit firstly controls the switch S5 in the OFF state such that the seven light-emitting elements connected in parallel with the switch S5 are lighten, and the residuary light-emitting elements may be controlled by the above controlling method to control the switches S1-S4. For example, if the twenty light-emitting elements should be controlled to be lighten, the fifth switch S5 is firstly controlled in the OFF state, and the seven light-emitting elements (D16-D22) connected in parallel therewith are lighten. Then the residuary thirteen light-emitting elements are lighten by controlling the switches S1-S4 in the ON or OFF state, that is, the switches S1, S3 and S4 are in the OFF state and only the switch S2 is in the ON state. The controlling method for controlling the switches S1-S4 in the ON or OFF state may be performed by the binary method of the second exemplary embodiment. That is, the binary number of 13 is “1101”, that is “S4S3S2S1” is “1101” respectively. That is, for the switches S1 to S5, only the switch S2 is in the ON state of “0”, and other switches are in the OFF state of “1”. That is, “11101” may light the twenty light-emitting elements. If lighting the twenty-one light-emitting elements, the switch S5 is in the OFF state and the seven light-emitting elements are lighten. For the residuary fourteen light-emitting elements, the binary number thereof is “1110”, therefore “S4S3S2S1” is “1110” respectively, that is the sequence from S5 to S1 is “11110”.

Although the exemplary embodiment cannot distribute the light-emitting elements of the power of 2 to all of the switches, the exemplary embodiment may use the connection to form the light-emitting element subunits, and cooperate the switch-controlling circuit to light the light-emitting elements of any number from 0 to N1 by the above controlling method. Thus, the exemplary embodiment is same to the second exemplary embodiment, and still accurately control the amount of light-emitting elements be lighten, and further improve the converting efficiency by more accurately controlling the amount of the lighten light-emitting elements.

### Fourth Exemplary Embodiment

Differences between this exemplary embodiment and the second and third exemplary embodiments are that, in this exemplary embodiment, the switches prior to the k-th switch are set with the light-emitting elements of the powers of 2, and the amount of the light-emitting elements connected in parallel with the k-th switch is less than 2^{k-1}, and of the switches after the k-th switch, each switch is connected in parallel with light-emitting elements whose number is configured by a compensation method. Therefore, the combinations may select any number from 1 to N1 and the light-emitting elements of any number from 0 to N1 may be controlled to be lighten.

In the driving circuit, the amount of the switches is n, and an m-th switch is connected in parallel with two terminals of Am light-emitting elements connected in series, to form an m-th light-emitting element subunit. In the exemplary embodiment, the switches are divided into three portions: one is the switches prior to the k-th switch (m is in a range from 1 to k−1), another is the k-th switch (m is equal to k), and the other are the switches after the k-th switch (m is in a range from k+1 to n). When m is in a range from 1 to k−1, Am is equal to 2^{m-1}, which is set with the light-emitting elements of the power of 2 connected in parallel with each of the switches; when m is equal to k, Ak is any number less than 2^{k-1}; and when m is in a range from k+1 to n, Am is a sum of a basic number and a compensation number. The basic number is double of Aₘ₋₁, each of compensation numbers may be any integral number from 0 to 2^{k-1}−Ak, and the maximum of the sum of the compensation numbers is 2^{k-1}−Ak.

For example, when k=4, that is the amount of the light-emitting elements connected in parallel with the fourth switch is less than 2^{k-1}, the first switch is still connected in parallel with A1=1 light-emitting element, to form a first light-emitting element subunit L1; a second switch is still connected in parallel with A2=2 light-emitting elements, to form a second light-emitting element subunit L2; a third switch is still connected in parallel with A3=4 light-emitting elements, to form a third light-emitting element subunit L3. In the second and third exemplary embodiments, the fourth switch should be connected in parallel with eight light-emitting elements connected in series; however, in this exemplary embodiment, the fourth switch is connected in parallel with A4=5 light-emitting elements connected in series to form a fourth light-emitting element subunit L4, which is less by 3 in comparison with 8. Then, the fifth switch is connected in parallel with A5=(a basic number+a compensation number)=(2×A4+the compensation number) light-emitting elements connected in series, and so on, and the n-th switch is connected in parallel with An=(a basic number+a compensation number)=(2×An−1+the compensation number) light-emitting elements connected in series. Wherein, each of the compensation numbers may be any integral number from 0 to 2^{k-1}−5, and the sum of the compensation numbers is not larger than 2^{k-1}−5.

A first condition: the amounts of the light-emitting elements of each groups as follows:

A1=1, A2=2, A3=4, A4=5, A5=10, A6=20, A7=40, that is, all of the compensation numbers are 0, which satisfies the condition that each of the compensation numbers is an integral number from 0 to 3, and the sum of the compensation numbers is not larger than three. All of the compensation numbers are 0, that is, the three light-emitting elements lacked in the fourth switch are not compensated into the later light-emitting element subunits. At the moment, the seven switches are configured for controlling N1=82 light-emitting elements to light. When controlling the twenty-nine light-emitting elements to light, the arrangement of “S7 S6S5S4S3S2S1” is “0101100”, that is, the switches S6, S4, S3 are in the OFF state of “1” and the switches S1, S2, S5, S7 are in the ON state of “0”. Therefore, the amount of light-emitting elements be lighten in the normal operation are 20+5+4=29. The number array of 1, 2, 4, 5, 10, 20, 40 can combine any number of 1-82. Therefore, the seven light-emitting element subunits formed in the condition, can control the light-emitting elements of any number from 0 to 82 to be lighten.

A second condition: the amounts of the light-emitting elements of each groups as follows:

A1=1, A2=2, A3=4, A4=5, A5=13=2×5+3, A6=26 A7=52, that is, the compensation number of the fifth light-emitting element subunit is three, and other compensation numbers are all 0, which satisfies the condition that each of the compensation numbers is an integral number from 0 to 3 and the sum of the compensation numbers is not larger than 3. At the moment, it means the three light-emitting elements lacked in the fourth switch are compensated into the later fifth light-emitting element subunit at one time. At the moment, the seven switches are configured for controlling N1=103 light-emitting elements to light. Similarly, the number array of 1, 2, 4, 5, 13, 26, 52 can combine any number of 1-103. Therefore, the seven light-emitting element subunits formed in the condition, can control the light-emitting elements of any number from 0 to 103 to be lighten.

A third condition: the amounts of the light-emitting elements of each groups as follows:

A1=1, A2=2, A3=4, A4=5, A5=11=2×5+1, A6=24=24=2×11+2, A7=48, that is, the compensation number of the fifth light-emitting element subunit is 1, the compensation number of sixth light-emitting element subunit is 2, and other compensation number is 0, which satisfies the condition that each of the compensation numbers is an integral number from 0 to 3, and the sum of the compensation numbers is not larger than 3. At the moment, it means the three light-emitting elements lacked in the fourth switch are compensated into the later fifth light-emitting element subunit and the later sixth light-emitting element subunit respectively. At the moment, the seven switches are configured for controlling N1=95 light-emitting elements to light. Similarly, the number array of 1, 2, 4, 5, 11, 24, 48 can combine any number of 1-95. Therefore, the seven light-emitting element subunits formed in the condition, can control the light-emitting elements of any number from 0 to 95 to be lighten.

According to the above condition, the lacked number may be not compensated, or may be compensated at one time, or may be compensated over and over, to control the light-emitting elements of any number to be lighten. That is, the exemplary embodiment divides the switches into three portions based on the switches prior to the k-th switch (m is from 1 to k−1), the k-th switch (m is k), the switches after the k-th switch, and set the amounts of the light-emitting elements connected in parallel with each of the switches, to light the light-emitting elements of any number from 0 to N1. Therefore, it also can accurately control the amount of light-emitting elements be lighten, and further improve the converting efficiency by more accurately controlling the amount of light-emitting elements be lighten.

### Fifth Exemplary Embodiment

Differences between this exemplary embodiment and the second exemplary embodiment are that, this exemplary embodiment is more improved based on the second exemplary embodiment, the first light-emitting element subunit to the n-th light-emitting element subunit are connected in series, and one terminal of the n light-emitting element subunits connected in series is coupled to a positive output terminal of the rectifying circuit, and another terminal thereof is coupled to a negative output terminal of the rectifying circuit. The N1 light-emitting elements are connected in series, that is, an anode of the first light-emitting element of the first light-emitting element subunit is connected to the positive terminal of the rectifying circuit or connected to the positive terminal of the rectifying circuit through the first current-controlling circuit; a cathode of the N1-th light-emitting element is connected to the negative terminal of the rectifying circuit or connected to the negative terminal of the rectifying circuit through the first current-controlling circuit. The driving circuit further comprises n1 switches, one terminal of each of the n1 switches is all connected to the cathode of the N1-th light-emitting element, and another terminal thereof is connected to a connection terminal between the cathode and the anode of two light-emitting elements.

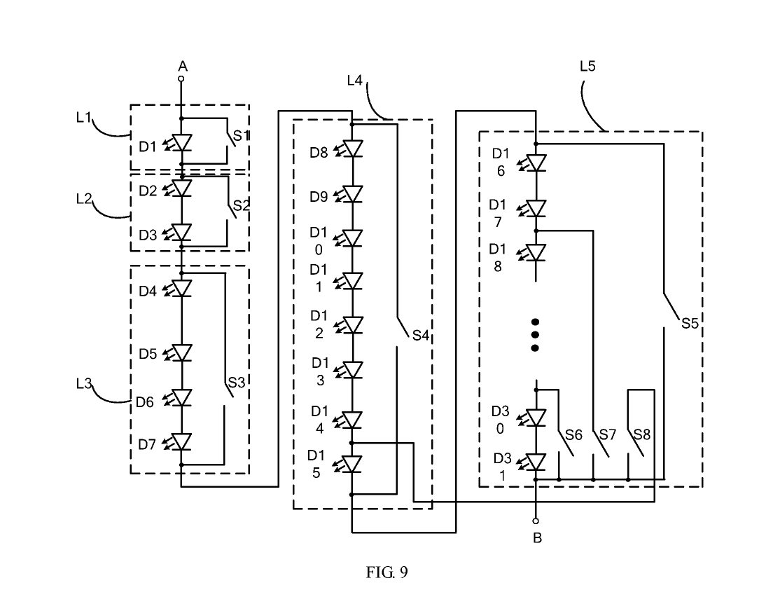

As shown in FIG. 9, which is a structural view of the light-emitting element subunits of the exemplary embodiment, the exemplary embodiment increases three switches (S6, S7, and S8) to improve, based on the structure of the light-emitting element subunits as shown in FIG. 7. The five switches S1 to S5, and the thirty-one light-emitting elements are connected to form the five light-emitting element subunits L1 to L5 connected in series, which are same to those of the second exemplary embodiment. After connecting in series, one terminal “A” of the five light-emitting element subunits (that is, one terminal of the first light-emitting element subunit) is connected to the positive terminal of the rectifying circuit, and another terminal “B” of the five light-emitting element subunit (that is, one terminal of the fifth light-emitting element subunit) is connected to the negative terminal of the rectifying circuit. The thirty-one light-emitting elements are connected in series. The driving circuit increases three switches S6, S7 and S8. One terminal of the switch S6 is connected to the cathode of the 31th light-emitting element D31, and another terminal thereof is connected to the connection terminal between the cathode and the anode of any two light-emitting elements of the light-emitting element subunit L5, such as the connection terminal between the cathode of the light-emitting element D29 and the anode of the light-emitting element D30 as shown in FIG. 9. One terminal of the switch S7 is connected to the cathode of the 31th light-emitting element D31, and another terminal thereof is connected to the connection terminal of the cathode and the anode of any two light-emitting elements of the light-emitting element subunit L5, such as the connection terminal of the cathode of the light-emitting element D17 and the anode of the light-emitting element D18 as shown in FIG. 9. One terminal of the switch S8 is connected to the cathode of the 31th light-emitting element D31, and another terminal thereof is connected to the connection terminal of the cathode and the anode of any two light-emitting elements, such as the connection terminal of the cathode of the light-emitting element D14 and the anode of the light-emitting element D15 as shown in FIG. 9.

In operation, the original five switches S1 to S5 are controlled to light the light-emitting elements of any number of 0-31. In addition, the switch S6 is increased. When controlling to light the twenty-nine light-emitting elements, the second exemplary embodiment controls the switches S1, S3, S4 and S5 in the off state, and controls the switch S2 in the ON state. After increasing the switch S6, the switches S1-S5 are controlled in the OFF state to light the corresponding thirty-one light-emitting elements, and the switch S6 is controlled in the ON state to short the corresponding the light-emitting elements D30 and D31, such that the light-emitting elements D30 and D31 are shut up and the twenty-nine light-emitting elements are lighten. That is, by increasing the switches, the switch S2 changes in the OFF state from in the ON state originally and the switch S6 is in the ON state. The switch S2 is far away from the negative terminal of the rectifying circuit, that is, the location of the equivalent ground terminal of the circuit, and the switch S6 is adjacent to the equivalent ground terminal of the circuit. If the switches are performed by the triode, the required voltage of the base of the switch S6 in the ON state is lower than the required voltage of the base of the switch S2 in the ON state. Therefore, the switches are increased, such that when controlling the light-emitting elements of some numbers to light, the voltage of the required control signal is lower, and the controlling cost thereof is lower.

Similarly, the switch S7 is increased. When controlling to light the seventeen light-emitting elements, the second exemplary embodiment controls the switches S1 and S5 in the OFF state to light the corresponding 1+16=17 light-emitting elements, and controls the switches S2 to S4 in the ON state. After increasing the switch S7, the switches S1 to S5 are all controlled in the OFF state to light the corresponding thirty-one light-emitting elements, and the switch S7 is controlled in the ON state to short and shut up the fourteen light-emitting elements D18-D31, such that the 31−14=17 light-emitting elements are lighten. Therefore, it changes to control the switch S7 in the ON state from controlling the switches S2, S3 and S4 in the ON state originally, such that the voltage of the required control signal is lower and the controlling cost thereof is decreased. The switch S8 is increased. When controlling to light the fourteen light-emitting elements, the second exemplary embodiment controls the switches S2 to S4 in the OFF state to light the corresponding 2+4+8=14 light-emitting elements, and control the switches S1 and S5 in the ON state. After increasing the switch S8, the switches S1 to S5 are all controlled in the OFF state to light the corresponding thirty-one light-emitting element, and the switch S8 is controlled in the ON state to short and shut up the seventeen light-emitting elements D15-D31, such that the 31−17=14 light-emitting elements are lighten. Therefore, it changes to control the switch S8 in the ON state from controlling the switches S1 and S5 in the ON state originally, such that the voltage of the required control signal is lower and the controlling cost thereof is decreased.

In summary, the driving circuit for the light-emitting elements of the exemplary embodiment, may further decrease the controlling cost of the circuit based on the second exemplary embodiment, except for accurately controlling the amount of the lighten light-emitting elements as shown in the second exemplary embodiment.

### Sixth Exemplary Embodiment

Differences between this exemplary embodiment and the second exemplary embodiment are that, this exemplary embodiment is more improved based on the second exemplary embodiment, the first light-emitting element subunit to the n-th light-emitting element subunit are connected in series, and one terminal of the n light-emitting element subunits connected in series is coupled to a positive output terminal of the rectifying circuit, and another terminal thereof is coupled to a negative output terminal of the rectifying circuit. The N1 light-emitting elements are connected in series that is, an anode of the first light-emitting element of the first light-emitting element subunit is connected to the positive terminal of the rectifying circuit or connected to the positive terminal of the rectifying circuit through the first current-controlling circuit; a cathode of the N1-th light-emitting element is connected to the negative terminal of the rectifying circuit or connected to the negative terminal of the rectifying circuit through the first current-controlling circuit. The driving circuit further comprises a charge-discharge circuit, and the charge-discharge circuit comprises a charge-discharge switch SWX, a charge-discharge capacitor C1 and a second current-controlling circuit. One terminal of the charge-discharge circuit is connected to the cathode of the

$$N 1 - \frac{Uc 1 - Δ U 2}{U 0} - th$$

light-emitting element, and another terminal thereof is connected to the negative terminal of the rectifying circuit. Wherein, Uc1 is the charge-discharge operation voltage of the charge-discharge capacitor C1, ΔU2 is the operation voltage of the second current-controlling circuit, and U0 is the operation voltage of each light-emitting element.

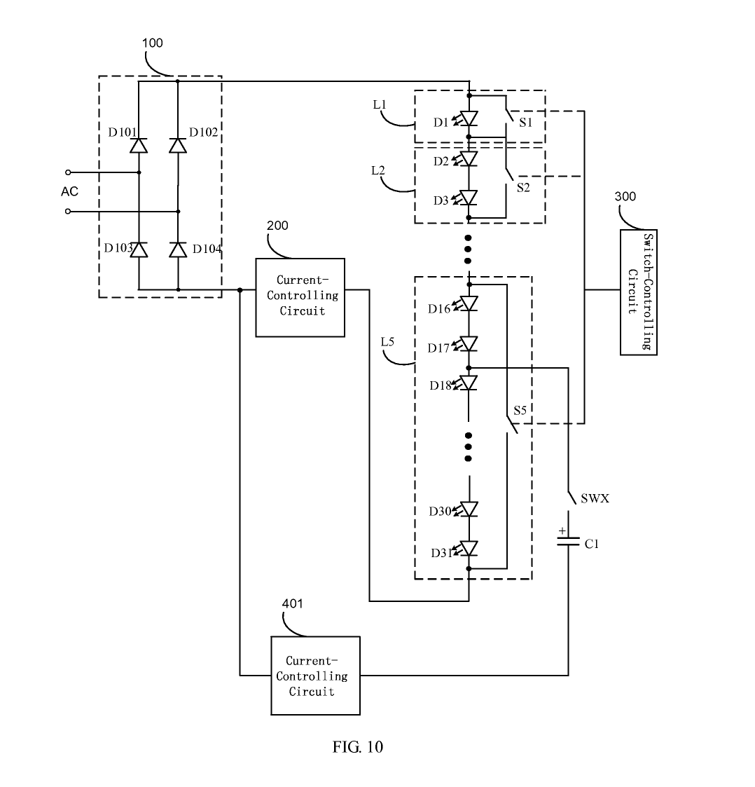

As shown in FIG. 10, which is a structural view of the driving circuit for the light-emitting elements of the exemplary embodiment, the driving circuit comprises a rectifying circuit 100, a first current-controlling circuit 200, a plurality of switches (S1, S2, . . . , S5), a switch-controlling circuit 300 and a charge-discharge circuit.

The connection of the rectifying circuit 100, the first current-controlling circuit 200, the plurality of switches and the switch-controlling circuit 300 are same to those of the first exemplary embodiment as shown in FIG. 4, and it will not be described in follows. The switches S1 to S5 and the light-emitting elements be driven, form a plurality of light-emitting element subunits L1 to L5, which are same to those of the second exemplary embodiment as shown in FIG. 7, and it will not be describe in follows.

The charge-discharge circuit of the exemplary embodiment comprises the charge-discharge switch SWX, the charge-discharge capacitor C1 and the second current-controlling circuit 401. One terminal of the charge-discharge circuit is connected to the cathode of the

$$N 1 - \frac{Uc 1 - Δ U 2}{U 0} - th$$

light-emitting element, by taking integral part of the calculated result of

$$\frac{Uc 1 - Δ U 2}{U 0} ,$$

and another terminal thereof is connected to the negative terminal of the rectifying circuit. Wherein, Uc1 is the charge-discharge operation voltage of the charge-discharge capacitor C1, ΔU2 is the operation voltage of the second current-controlling circuit, and U0 is the operation voltage of each light-emitting element. In this exemplary embodiment, the amount N1 of the light-emitting elements is equal to 31. According to the parameters of the charge-discharge capacitor C1, the second current-controlling circuit 401 and the light-emitting element,

$$\frac{Uc 1 - Δ U 2}{U 0}$$

is calculated to 14. Therefore, one terminal of the charge-discharge circuit is connected to the cathode of the

$$N 1 - \frac{Uc 1 - Δ U 2}{U 0} = 17 th$$

light-emitting element D17, and another terminal thereof is connected to the negative terminal of the rectifying circuit 100. In the charge-discharge circuit, the capacitor C1 is configured for storing the energy when charging and releasing the stored energy to supply the electrical power when discharging. The second current-controlling circuit 401 is configured for controlling the current passing through the charge-discharge circuit when charging the capacitor C1, and the current passing through the branch of the fourteen light-emitting elements connected in parallel therewith under the control of the first current-controlling circuit 200. The sum of the two current is in a range of the operation current of the light-emitting elements, and the detailed structure is same to the first current-controlling circuit 200. The charge-discharge circuit can discharge the 14 light-emitting elements connected in parallel therewith. In should be noted that, one terminal of the charge-discharge circuit of the exemplary embodiment is connected to the cathode of the 17th light-emitting element D17, that is, the charge-discharge circuit is in the fifth light-emitting element subunit. In other embodiment, if the charge-discharge voltage is higher, the amount of the light-emitting elements connected in parallel with the charge-discharge circuit may be higher, such as twenty light-emitting elements. That is, one terminal of the charge-discharge circuit is connected to the cathode of the 11th light-emitting element, therefore, the charge-discharge circuit crosses over the fourth light-emitting element subunit and the fifth light-emitting subunit.

After increasing the charge-discharge circuit in the drive circuit, when the instantaneous value of the DC voltage outputted from the rectifying circuit 100 is high, such as at the location adjacent to the peak, most of the N1=31 light-emitting elements are lighten. For example, when the twenty-seven light-emitting elements should be lighten at the location adjacent to the peak, the switches S1, S2, S4 and S5 are in the OFF state and the switch S3 is in the ON state, that is, the 1+2+8+16=27 light-emitting elements are lighten. At the moment, the sixteen light-emitting elements of the fifth light-emitting element subunit are all lighten. At the moment, the charge-discharge switch SWX of the charge-discharge circuit is controlled in the ON state, the charge-discharge circuit is connected to the fore light-emitting elements D1 to D3, and the route formed by the switch S3 and the light-emitting elements D8 to D17 are charged. When the instantaneous value of the DC voltage outputted from the rectifying circuit 100 is low, and lower than the discharging voltage provided by the charge-discharge circuit, such as, at the location adjacent to 0, if not increasing the charge-discharge circuit, only a few of the N1=31 light-emitting elements are lighten. For example, when the 1+2=3 light-emitting elements should be lighten at the location adjacent to 0, the switches S1, S2 are in the OFF state, and the switches S3, S4 and S5 are in the ON state, that is, the 1+2=3 light-emitting elements are lighten. After increasing the charge-discharge circuit, the switches S1 to S5 are controlled in the OFF state. At the moment, the instantaneous value of the DC voltage is low and cannot light the light-emitting elements, the charge-discharge circuit discharges the fourteen light-emitting elements connected in parallel therewith. Therefore, it can change from the three light-emitting elements are lighten originally, to the fourteen light-emitting elements are lighten. Therefore, when the instantaneous value of the DC voltage is lower than the discharging voltage provided by the charge-discharge circuit, the fourteen light-emitting elements are throughout lighten, to avoid the illumination of the whole light-emitting elements dropping off greatly and avoid the illumination thereof changing largely, such that the whole illumination of the light-emitting elements is steadily during the period of the DC voltage, and the total illumination is steadily and the light emits steadily. According to the operation principle of the charge-discharge circuit, the charge-discharge circuit may be electrically coupled dual-directionally. The second current-controlling circuit 401 requires the charge-discharge capacitor C1 may be electrically coupled reverse-directionally when discharging. When electrically coupling reverse-directionally, it does not need to limit the current, or connect a diode in parallel between the input terminal and the output terminal of the circuit, to make the current passing through the diode when the capacitor discharges, and not passing through the original current-controlling circuit reverse-directionally.

According to the connection and the operation principle of the charge-discharge circuit, the operation of the charge-discharge circuit is not related to the distribution of the light-emitting elements connected in parallel with each of the switches of the light-emitting element subunits. The present invention may increase the charge-discharge circuit into the driving circuits of the first, third to fifth exemplary embodiments, besides the second exemplary embodiment. In addition, the charge-discharge switch SWX, the charge-discharge capacitor C1 and the second current-controlling circuit 401 of the charge-discharge circuit are connected in series, thus the sequence of the three components may be altered and can achieve the same effect, and it may be a random sequence thereof.

The driving circuit for the light-emitting elements of the exemplary embodiment, is same to that of the first exemplary embodiment, can it can adjust the amount of the lighten light-emitting element according to the instantaneous value of the DC voltage outputted from the fore rectifying circuit 100, such that the electrical energy of the AC power source can be maximally converted into the light energy, and improve the converting efficiency. In addition, the exemplary embodiment increase the charge-discharge circuit, such that the whole illumination of the light-emitting elements is steadily during the period of the DC voltage, and the total illumination thereof change steadily, and light emits steadily.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A driving circuit for light-emitting elements, comprises a rectifying circuit and a first current-controlling circuit; input terminals of the rectifying circuit are connected to output terminals of an AC power source, the first current-controlling circuit and a plurality of light-emitting elements to be driven are connected in series, and then are connected between two output terminals of the rectifying circuit; wherein,
the driving circuit further comprises a plurality of switches and a switch-controlling circuit;
the switches are connected in parallel with two terminals of one light-emitting elements or some light-emitting elements connected in series to form a plurality of light-emitting element subunits;
control-signal output terminals of the switch-controlling circuit are connected to control terminals of the switches respectively, to control the switches in ON-OFF state according to an instantaneous value of a DC voltage outputted from the rectifying circuit, for controlling an amount of light-emitting elements to be lighten.

2. The driving circuit according to claim 1, wherein the light-emitting element is selected from the group consisting of light-emitting diodes, organic light-emitting diodes, polymer light-emitting diodes and laser diodes.

3. The driving circuit according to claim 2, wherein the switch-controlling circuit calculates the amount of the light-emitting elements to be lighten by taking an integral part of a calculated result according to a formula of:
$$\frac{U - Δ U 1}{U 0} ,$$
wherein,
U represents an instantaneous value of the DC voltage outputted from the rectifying circuit;
ΔU1 represents an operation voltage required by the first current-controlling circuit operating steadily; and
U0 represents an operation voltage of a single light-emitting element.

4. The driving circuit according to claim 2, wherein,
the amount of the switches is n;
a m-th switch is connected in parallel with two terminals of Am light-emitting elements connected in series to form a m-th light-emitting element subunit, wherein m is from 1 to n;
the n light-emitting element subunits are connected in series, and a sum of amounts of light-emitting elements comprised in each of the n light-emitting element subunit is N1;
the n numbers of A1 to An are formed to satisfy the conditions of the rules of combination to get any number from 1 to N1.

5. The driving circuit according to claim 4, wherein the value of Am is 2^{m-1}, m is from 1 to n; N1 is equal to 2ⁿ−1.

6. The driving circuit according to claim 5, wherein the switch-controlling circuit controls an amount of light-emitting elements be lighten according to a following method that comprises:
1) the switch-controlling circuit converting the amount of the light-emitting elements to be lighten into a binary number with n bits;
2) the switch-controlling circuit controlling the n switches according to n bits of binary number respectively, wherein a m-th bit of the binary number from right to left correspondingly controls the m-th switch; while the m-th bit is 0, the m-th switch is correspondingly controlled in the ON state; while the m-th bit is 1, the m-th switch is correspondingly controlled in the OFF state.

7. The driving circuit according to claim 5, wherein the first light-emitting element subunit to the n-th light-emitting element subunit are connected in series, the N1 light-emitting elements are connected in series; the driving circuit further comprises n1 switches, one terminal of each of the n1 switches is connected to a cathode of a N1-th light-emitting element, and another terminal thereof connected to a connection terminal of a cathode and an anode of any two light-emitting elements respectively.

8. The driving circuit according to claim 4, wherein the value of Am is 2^{m-1}, m is from 1 to n−1; the value of An is N1−(2ⁿ⁻¹−1), and N1 is larger than 2ⁿ⁻¹−1 but less than 2ⁿ−1.

9. The driving circuit according to claim 4, wherein
while m is from 1 to k−1, the value of Am is 2^{m-1}; the value of Ak is less than 2^{k-1};
while m is from k+1 to n, the value of Am is a sum of a basic number and a compensation number, the basic number is double of Aₘ₋₁, each of the compensation numbers is an integral number from 0 to 2^{k-1}−Ak, and a sum of the compensation numbers is no larger than 2^{k-1}−Ak.

10. The driving circuit according to claim 4, wherein the sum N1 of the amounts of the light-emitting elements comprised in each of the light-emitting element subunits is less than the amount N of the light-emitting elements of the driving circuit to be driven.

11. The driving circuit according to any one of claims 1-10, wherein
the first light-emitting element subunit to the n-th light-emitting element subunit are connected in series, the N1 light-emitting elements are connected in series;
the driving circuit further comprises a charge-discharge circuit which includes a charge-discharge switch, a charge-discharge capacitor and a second current-controlling circuit connected in series;
one terminal of the charge-discharge circuit is connected to an cathode of a
$$N 1 - \frac{Uc 1 - Δ U 2}{U 0} - th$$
light-emitting element, and integral part of the result of
$$\frac{Uc 1 - Δ U 2}{U 0}$$
is taken; the other terminal of the charge-discharge circuit is connected to a negative terminal of the rectifying circuit;
wherein,
Uc1 represents a charge-discharge operation voltage of the charge-discharge capacitor;
ΔU2 represents an operation voltage of the second current-controlling circuit;
U0 represents an operation voltage of a single light-emitting element.

12. The driving circuit according to any one of claims 1-10, wherein at least one of the rectifying circuit, the first current-controlling circuit, the light-emitting elements, the switches and the switch-controlling circuit are integrated on an IC chip.

13. An illumination device having light-emitting elements, comprises a driving circuit and a plurality of light-emitting elements connected in series, the driving circuit is the driving circuit according to any one of claims 1-10.
